(19) United States
(12) Patent Application Publication
(10) Pub. No.: US 2017/0146205 A1
(43) Pub. Date: May 25, 2017

(54) Cover Plate

(71) Applicant: John LaForte, Freeport, NY (US)

(72) Inventor: John LaForte, Freeport, NY (US)

(21) Appl. No.: 15/279,045

(22) Filed: Sep. 28, 2016

Related U.S. Application Data
(60) Provisional application No. 62/258,100, filed on Nov. 20, 2015.

(51) Int. Cl. F21S 9/02; H05K 5/03; F21V 23/04; F21V 23/00; F21V 3/04; F21V 7/05

(52) U.S. Cl. CPC F21S 9/02; F21V 3/049; F21V 7/05; F21V 23/0464; F21V 23/0442; F21V 3/0436; F21V 23/002; H05K 5/03; F21Y 2115/10

(57) ABSTRACT

A cover plate for an electric switch or outlet box includes a laminated base member with a light-transmitting core, a front diffuser sheet, end a rear diffuser sheet, as well high efficiency light emitting diodes positioned in the edge of the base member. The LEDs are powered by batteries.

### CROSS-REFERENCE TO RELATED APPLICATION

This application claims the priority of U.S. Provisional Application 62/258,100, filed Nov. 20, 2015, hereby incorporated by reference.

### BACKGROUND OF THE INVENTION

Field of the Invention

The present invention relates to cover plates for electric boxes such as electric outlet boxes and electric boxes housing switches.

Background of the Invention

Electric boxes formed from metal or synthetic polymer materials are conventionally provided to securely house electric devices such as electric outlets and light switches. Conventionally, each such box is sealed against electric hazards after the installation of an outlet or light switch with a cover plate formed of painted steel or a synthetic polymer material. Night lights are well known to provide at least some minimal illumination to dark interior rooms. Such night lights typically take the form of low illumination devices operating on house current and plugged directly into electric outlets. While such conventional night lights serve useful purposes, they lose their efficacy in the event of a power failure. Further, because they require house current for operation, they cannot be used to locate light switches in a darkened room. One approach to the problem of identifying light switches in darkened rooms is provided by U.S. Pat. Nos. 6,423,900, and 9,035,180, and 9,362,728, the entireties of which are incorporated by reference, which discloses active cover plates including pairs of electrically conducting springs for drawing power from the terminals of a standard electrical device positioned in an electric box. The power is applied to an active load embedded within the cover plate, such as an electroluminescent panel. In the event of a power failure, the active load is not powered by the device.

### SUMMARY OF THE INVENTION

The present invention provides a cover plate for a standard electric device. The cover plate comprises a laminated base member including a light-transmitting core, a front diffuser sheet, and a rear diffuser sheet. The base member has at least one edge, and can be generally rectangular and have four edges. The cover plate includes at least one light emitting diode, with the at least one light emitting diode being positioned in an edge of the laminated base member. The cover plate further includes at least one battery for powering the at least one light-emitting diode. In addition, the cover plate also includes a plurality of conductors for conducting electrical energy from the at least one battery to the at least one light emitting diode. The cover plate preferably includes at least one switch for controlling the provision of electrical energy to the at least one light emitting diode. Preferably, the at least one light emitting diode is positioned in an aperture formed in an edge of the base member. Preferably, a light-reflecting sheet is provided between the at least one light-emitting diode and the front diffuser sheet. In addition, it is preferred that a light-reflecting sheet is also provided between the at least one light-emitting diode and the rear diffuser sheet. Preferably, the front diffuser sheet and the rear diffuser sheet are formed from a translucent material. Optionally, the core of the base member includes a front surface and a rear surface, and the front surface is provided with a plurality of light diffusing elements. Optionally, the at least one switch is manually operable. Optionally, in one embodiment the cover plate further includes a sensor for sensing the level of ambient light proximate the switch plate. In this embodiment, it is preferred that the at least one switch operates to provide electrical energy to the at least one light-emitting diode when the level of ambient light proximate the cover plate falls below a first predetermined threshold, and to stop the provision of electrical energy to the at least one light-emitting diode when the level of ambient light proximate the cover plate rises above a second predetermined threshold. Preferably, the at least one light-emitting diode comprises a plurality of light-emitting diodes positioned in one edge of the core. Optionally, the cover plate further includes a frame around the edges of the laminated base member. Preferably, the at least one light-emitting diode is a high efficiency diode. In one present embodiment, the core is formed from polycarbonate. In another present embodiment, the core is formed from polyacrylate.

### BRIEF DESCRIPTION OF THE DRAWINGS

FIG. 1 is a right side elevational view of a cover plate according to a presently preferred embodiment of the present invention.

FIG. 2 is a front elevational view of the core of the cover plate of FIG. 1.

FIG. 3 is a sectional elevational view of the cover plate of FIG. 1 taken along the line 3-3 of FIG. 1.

FIG. 4 is a rear elevational view of the cover plate of FIG. 1.

FIG. 5 is a front elevational view of a second embodiment of the cover plate of the present invention.

FIG. 6 is a rear elevational view of the cover plate of FIG. 5.

FIG. 7 is a sectional elevation view of a cover plate of a third embodiment of the present invention.

### DETAILED DESCRIPTION

The present invention provides a cover plate for a standard electric device, such an electric switch fed with house current and controlling a light switch or an outlet for house current. The cover plate of the present invention advantageously provides illumination independently of the supply of house current.

As can be seen in FIG. 1, a right side elevational view of a first embodiment of the cover plate 10, the cover plate 10 includes a generally rectangular laminated base member 11 including a light-transmitting core 14, a front diffuser sheet 24, and a rear diffuser sheet 26.

The front diffuser sheet 24 is preferably formed from a thin translucent sheet of thermoplastic or thermosetting material. The rear diffuser sheet 26 is also preferably formed from a thin sheet of thermoplastic or thermosetting material. Alternatively the rear sheet 26 may be formed from a sheet of reflective material such as a mirrorized Mylar sheet.

The front diffuser sheet 24 and the rear diffuser sheet 26 are preferably adhered to the core 10 by any suitable adhesive mater al to form the base member 11, which in this embodiment has four edges.

While the cover plate 10 in this embodiment is generally rectangular, the cover plate 10 can assume any geometric or decorative shape.

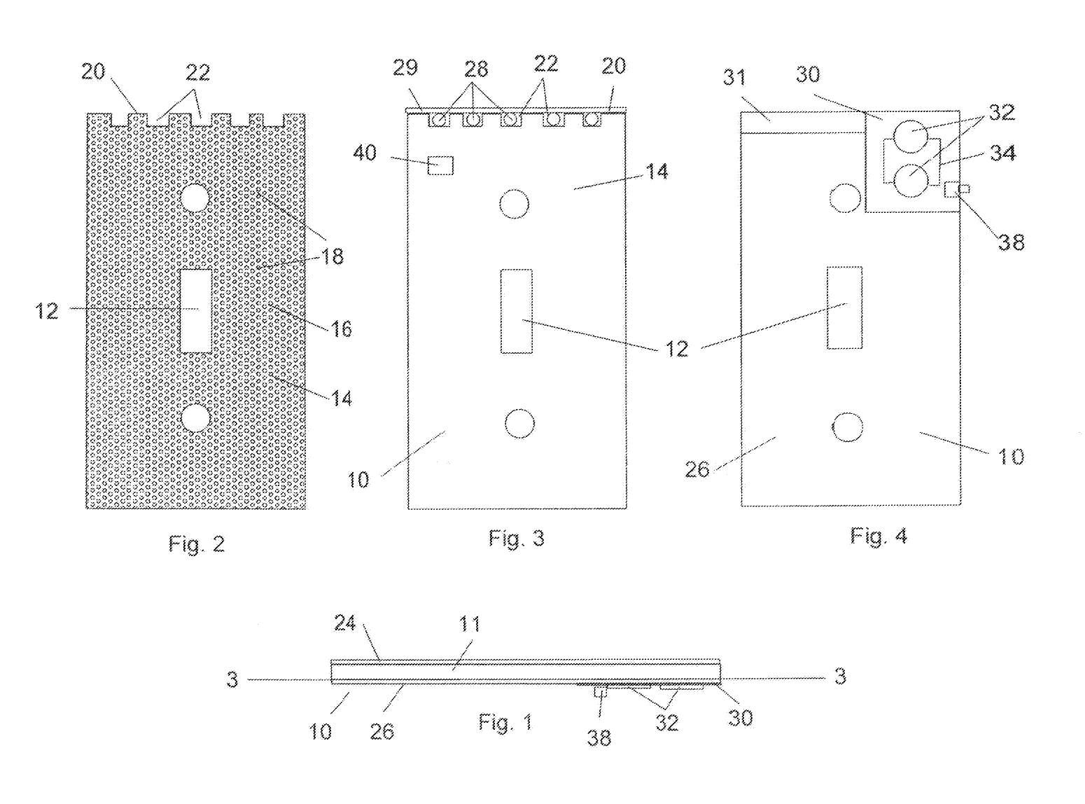

Optionally, the core 14 of the base member 11 includes a front surface 16 and a rear surface, and the front surface 16 is provided with a plurality of light diffusing elements 18, shown in FIG. 2, which are formed on the front surface 16 by printing or a like process.

As can be seen in the sectional elevation view of FIG. 3, the cover plate 10 includes at least one light emitting diode 29, with the at least one light-emitting diode being positioned in an edge 20 of the laminated base member 11 in apertures 22 formed in the edge 20. Electric power is provided to the light-emitting diodes 28 by a terminal member 29 which is preferably adhered to the edge 20 to enclose the light-emitting diodes 28 within the apertures 22. Preferably, the rear of core 14 proximate the edge 20 is covered with a reflective strip 31 (FIG. 4) to direct light from light-emitting diodes 28 into the core 14. The core 14 is preferably formed from a polycarbonate material such as Makolon Lumen XT (Covestro AG, Leverkusen, DE), or a polyacrylate such polymethylmethacrylate available as Acrylite LED (Evonic Cyro LLC, Parsippany, N.Y.) or Lucite Lux light guide panel (Lucite International Inc., Cordova, Tenn.). The terminal member 29 can be formed from an LED edge lighting system such as the Tres Mate solderless system (FourStar LED, Golden Valley, Minn.).

In a presently preferred embodiment, as shown in FIG. 7, light-emitting diodes 28 are provided both along the top edge and at the bottom edge of the cover plate 10.

The cover plate 10 further includes at least one battery 32 (FIG. 4), such as a pair of lithium batteries connected in parallel, and mounted on a printed circuit board 30 for powering the light-emitting diodes 28, which are preferably high efficiency light-emitting diodes.

In addition, the cover plate 10 also includes a plurality of conductors 34 for conducting electrical energy from the battery or batteries 32 to the light emitting diodes 28.

The cover plate 10 preferably includes at least one switch 34 for controlling the provision of electrical energy to the light emitting diodes 28. Preferably, the light emitting diode 28 are positioned in aperture 22 (FIGS. 2 and 3) formed in an edge 20 of the core 14. Preferably, a light-reflecting sheet (not shown) is provided between the light-emitting diodes 28 and the front diffuser sheet 24. In addition, it is preferred that a light-reflecting sheet 31 is also provided between the light-emitting diodes 28 and the rear diffuser sheet 26.

Preferably, the front diffuser sheet 24 and the rear diffuser sheet 26 are formed from a translucent material.

Optionally, the at least one switch 38 is manually operable. Optionally, in one embodiment the cover plate further includes a sensor 40 (FIG. 3) for sensing the level of ambient light proximate the switch plate. In this embodiment, it is preferred that the switch 38 operates to provide electrical energy to the light-emitting diodes 28 when the level of ambient light proximate the cover plate falls below a first predetermined threshold, and to stop the provision of electrical energy to the at least one light-emitting diode 28 when the level of ambient light proximate the cover plate rises above a second predetermined threshold. For example, the sensor 40 can detect when a room becomes dark, and the cover plate can be programmed to turn on the light-emitting diodes 28 when the room becomes dark. Similarly, the cover plate can be programmed to increase the electrical energy provided to the light emitting diodes 28 when the room becomes brightly illuminated, so that the cover plate 10 remains noticeable.

Preferably, the at least one light-emitting diode comprises a plurality of light-emitting diodes 28 positioned in one edge 20 of the core 14, such as shown.

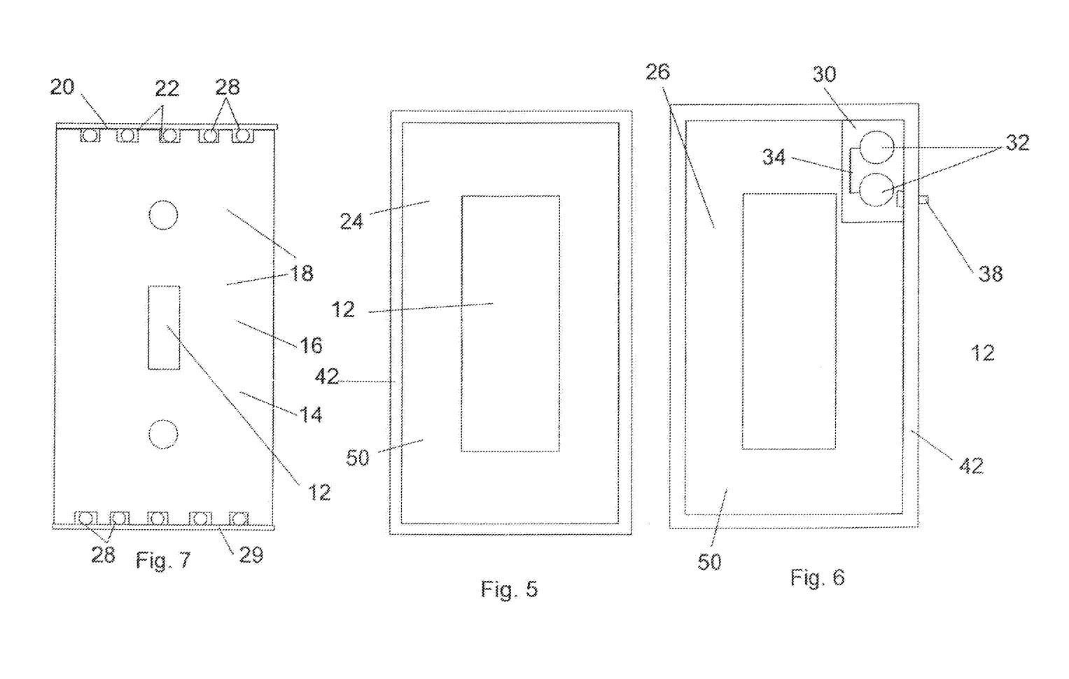

Optionally, as depicted in FIGS. 5 and 6 in one presently preferred embodiment the cover plate 50 further includes a frame 42 around the edges of the laminated base member.

This invention is not limited to the illustrative embodiments described above and encompasses any and all embodiments within the scope of the appended claims and their equivalents.

1. A cover plate comprising:
a) a laminated base member including a light-transmitting core, a front diffuser sheet, and a rear diffuser sheet, the base member having at least one edge;
b) at least one light emitting diode, the at least one emitting diode being positioned in the at least one edge of the laminated base member,
c) at least one battery for powering the at least one light-emitting diode;
d) a plurality of conductors for conducting electrical energy from the at least one battery to the at least one light emitting diode; and
e) at least one switch for controlling the provision of electrical energy to the at least one light emitting diode.

2. A cover plate according to claim 1 wherein the at least one light emitting diode is positioned in an aperture formed in the edge of the base member.

3. A cover plate according to claim 2 wherein a light-reflecting sheet is provided between the at least one light-emitting diode and the front diffuser sheet.

4. A cover plate according to claim 3 wherein a light-reflecting sheet is provided between the at least one light-emitting diode and the rear diffuser sheet.

5. A cover plate according to claim 1 wherein the front diffuser sheet and the rear diffuser sheet are formed from a translucent material.

6. A cover plate according to claim 1 wherein the core of the base member includes a front surface and a rear surface, the front surface being provided with a plurality of light diffusing elements.

7. A cover plate according to claim 1, wherein the at least one switch is manually operable.

8. A cover plate according to claim 1, wherein the cover plate further includes a sensor for sensing the level of ambient light proximate the switch plate.

9. A cover plate according to claim 8, wherein the at least one switch operates to provide electrical energy to the at least one light-emitting diode when the level of ambient light proximate the cover plate falls below a first predetermined threshold, and to stop the provision of electrical energy to the at least one light-emitting diode when the level of ambient light proximate the cover plate rises above a second predetermined threshold.

10. A cover plate according to claim 1 wherein the at least one light-emitting diode comprise a plurality of light-emitting diodes positioned in one edge of the core.

11. A cover plate according to claim 1 further comprising a frame around the edges of the laminated base member.

12. A cover plate according to claim 1 wherein the at least one light-emitting diode is a high efficiency light-emitting diode.

13. A cover plate according to claim 1 wherein the core is formed from a polycarbonate.

14. A cover plate according to claim 1 wherein the core is formed from a polyacrylate.
